(19) United States
(12) Patent Application Publication
(10) Pub. No.: US 2016/0079480 A1
(43) Pub. Date: Mar. 17, 2016

(54) SEMICONDUCTOR LIGHT-EMITTING DEVICE AND METHOD OF MANUFACTURING THE SAME

(71) Applicant: KABUSHIKI KAISHA TOSHIBA, Tokyo (JP)

(72) Inventors: Kei KANEKO, Yokohama Kanagawa (JP); Rei HASHIMOTO, Edogawa Tokyo (JP); Satoshi MITSUGI, Kawasaki Kanagawa (JP); Chie HONGO, Yokohama Kanagawa (JP)

(21) Appl. No.: 14/634,883

(22) Filed: Mar. 1, 2015

(30) Foreign Application Priority Data
Sep. 12, 2014 (JP) 2014-187110

(51) Int. Cl. H01L 33/44; H01L 33/24

(52) U.S. Cl. CPC H01L 33/44; H01L 33/24; H01L 2933/0025

(57) ABSTRACT

A semiconductor light-emitting device includes a first layer having a first surface and an opposing second surface. The first surface has a roughness including a bottom portion and a top portion. A light emitting layer is provided between the second surface and a second layer. An insulating layer is provided on the first surface. The insulating layer includes a first portion adjacent to the bottom portion and a second portion adjacent to the top portion along the first direction. The first portion has a thickness that is greater than a thickness of the second portion.

### CROSS-REFERENCE TO RELATED APPLICATION

This application is based upon and claims the benefit of priority from Japanese Patent Application No. 2014-187110, filed Sep. 12, 2014, the entire contents of which are incorporated herein by reference.

### FIELD

Embodiments described herein relate generally to a semiconductor light-emitting device and a method of manufacturing the same.

### BACKGROUND

In a semiconductor light-emitting device (for example, a light-emitting diode), the improvement in reliability is desirable.

### DESCRIPTION OF THE DRAWINGS

FIG. 1 is a schematic cross-sectional view illustrating a semiconductor light-emitting device according to a first embodiment.

FIG. 2 is a schematic cross-sectional view illustrating the semiconductor light-emitting device according to the first embodiment.

FIGS. 3A to 3F are schematic cross-sectional views illustrating steps of a method of manufacturing the semiconductor light-emitting device according to the first embodiment.

FIG. 4 is a schematic cross-sectional view illustrating another method of manufacturing the semiconductor light-emitting device according to the first embodiment.

FIG. 5 is a schematic cross-sectional view illustrating another semiconductor light-emitting device according to the first embodiment.

FIG. 6 is illustrates operational characteristics of a semiconductor light-emitting device.

FIG. 7 is a schematic cross-sectional view illustrating a semiconductor light-emitting device according to a second embodiment.

FIG. 8 is a schematic cross-sectional view illustrating another semiconductor light-emitting device according to the second embodiment.

FIG. 9 is a schematic cross-sectional view illustrating a semiconductor light-emitting device according to a third embodiment.

FIG. 10 is a schematic cross-sectional view illustrating another semiconductor light-emitting device according to the third embodiment.

FIG. 11 is a schematic cross-sectional view illustrating a semiconductor light-emitting device according to a fourth embodiment.

FIG. 12 is a flowchart illustrating a method of manufacturing a semiconductor light-emitting device according to a fifth embodiment.

### DETAILED DESCRIPTION

Embodiments provide a semiconductor light-emitting device having high reliability and a method of manufacturing the same.

According to one embodiment, a semiconductor light-emitting device includes a first layer having a first surface and a second surface opposing the first surface and spaced from the first surface in a first direction crossing the second surface. The first layer includes a first semiconductor layer of a first conductivity type. The first surface of the first layer has a roughness (concave/convex portions) including a bottom (valley) portion and a top (peak) portion. A first distance along the first direction between the bottom portion and the second surface is less than a second distance along the first direction between the top portion and the second surface. A light emitting layer is adjacent to or on the second surface. A second layer including a second semiconductor layer of a second conductivity type is one the light emitting layer such that the light emitting layer is between the second surface and the second layer in the first direction. An insulating layer is disposed on the first surface. The insulating layer includes a first portion adjacent to the bottom portion and a second portion adjacent to the top portion. The first portion of the insulating layer has a first thickness along the first direction that is greater than a second thickness of the second portion along the first direction.

In general, according to one embodiment, a semiconductor light-emitting device includes a first layer, a second layer, a third layer, and an insulating layer. The first layer has a first surface and a second surface, the first surface having a rough portion including a bottom portion and a top portion and the second surface being opposite to the first surface. The first layer includes a first semiconductor layer of a first conductivity type. The second layer includes a second semiconductor layer of a second conductivity type. The third layer is provided between the second surface and the second layer. The insulating layer is provided on the first surface. The insulating layer includes a first portion and a second portion, the first portion overlapping the bottom portion along a first direction moving from the second layer to the first layer, and the second portion overlapping the top portion along the first direction. The first portion includes a first end positioned on the bottom portion side and a second end positioned on a side opposite the first end. A distance between the second end and the second layer along the first direction is shorter than a distance between the top portion and the second layer along the first direction. A first thickness of the first portion along the first direction is larger than a second thickness of the second portion along the first direction.

As used herein a “layer” may comprise multiple layers, such that, for example, a light emitting layer may comprise several barrier layers and well layers stacked in alternation one upon the other.

Hereinafter, example embodiments will be described with reference to the drawings.

The drawings are schematic and conceptual such that, a depicted relationship between the thickness and the width of each component, a ratio between the sizes of components, and the like are not necessarily the same as found in an actual device. In addition, even when the same component is illustrated in different drawings, a dimension or a dimensional ratio may vary depending on the drawings.

In this disclosure and the respective drawings, the same or substantially similar component depicted in multiple drawings is represented by the same reference numeral, and the detailed description of a previously described aspect or element may not be repeated for each drawing.

### First Embodiment

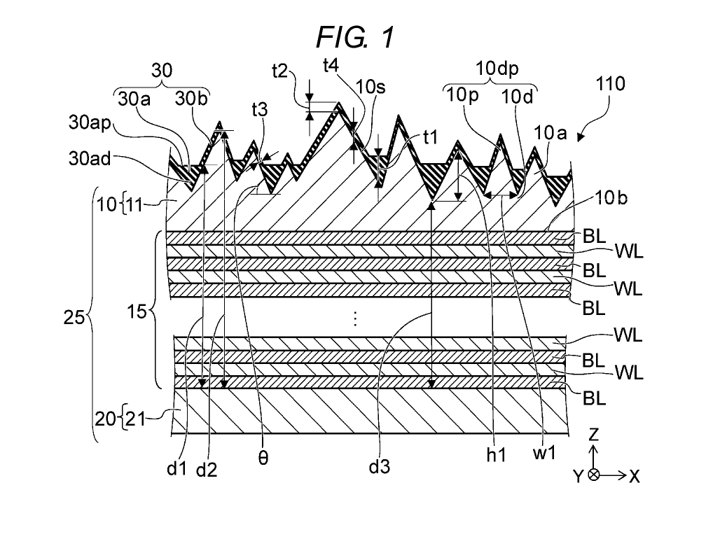

FIG. 1 is a schematic cross-sectional view illustrating a semiconductor light-emitting device according to a first embodiment.

As illustrated in FIG. 1, a semiconductor light-emitting device 110 includes a first layer 10, a second layer 20, a third layer 15, and an insulating layer 30.

The first layer 10 includes a first surface 10a and a second surface 10b. The first surface 10a has a rough portion 10dp. The second surface 10b is opposite to the first surface 10a. The first layer 10 includes a first semiconductor layer 11 of a first conductivity type. In this example, the entire portion of the first layer 10 is the first semiconductor layer 11. However, as described below, the first layer 10 may further include other layers in addition to the first semiconductor layer 11.

The second layer 20 includes a second semiconductor layer 21 of a second conductivity type. The second layer 20 is separated from the first layer 10.

For an example, the first conductivity type is an n-type, and the second conductivity type is a p-type. However, in some embodiments, the first conductivity type may be a p-type, and the second conductivity type may be an n-type. Hereinafter, in the specific examples discussed below, the first conductivity type is the n-type, and the second conductivity type is the p-type.

A direction going from the second layer 20 to the first layer 10 is set as a Z axis direction. One direction perpendicular to the Z axis direction is set as an X axis direction. Another direction perpendicular to the Z axis direction and the X axis direction is set as a Y axis direction. The Z axis direction is set as a first direction in this example.

The third layer 15 is provided between the second surface 10b of the first layer 10 and the second layer 20. A laminate 25 includes the first layer 10, the second layer 20, and the third layer 15.

The third layer 15 is, for example, a light-emitting layer. The third layer 15 includes, for example, a barrier layer BL and a well layer WL. In this example, plural barrier layers BL and plural well layers WL are provided. The plural barrier layers BL and the plural well layers WL are alternately disposed along the Z axis direction. In some embodiments, a single well layer WL may be provided.

The first layer 10, the second layer 20, and the third layer 15 are formed of, for example, a nitride semiconductor.

As described below, a current is supplied to the third layer 15 through the first layer 10 and the second layer 20, and thus light is emitted from the third layer 15. A peak wavelength of the emitted light is, for example, 380 nm to 800 nm. The intensity of the emitted light is the maximum at the peak wavelength.

The rough portion 10dp provided on the first surface 10a includes a bottom portion 10d and a top portion 10p. A distance between the bottom portion 10d and the second layer 20 is shorter than a distance between the top portion 10p and the second layer 20. For example, a distance between the bottom portion 10d and the second layer 20 is shorter than an average distance between the first surface 10a and the second layer 20. A distance between the top portion 10p and the second layer 20 is longer than an average distance between the first surface 10a and the second layer 20.

For example, the bottom portion 10d is included in a portion of the first surface 10a that is lower than an average position of the rough portion 10dp. For example, the top portion 10p is included in a portion of the first surface 10a that is higher than the average position of the rough portion 10dp.

In this example, the bottom portion 10d is positioned in the first semiconductor layer 11. The bottom portion 10d overlaps the first semiconductor layer 11 in a direction parallel to an X-Y plane.

A width w1 of the rough portion 10dp provided in the first layer 10 is, for example, the same as the length of an X-Y plane between two nearest bottom portions 10d. The width w1 is, for example, 0.8 times to 3 times (for example, 1 time to 2 times) as large as the peak wavelength. The width w1 is, for example, preferably from 200 nm to 500 nm. A distance between the top portions 10p of the rough portions 10dp is, for example, 0.8 times to 3 times (for example, 1 time to 2 times) as large as the peak wavelength. A distance between the top portions 10p is, for example, preferably from 200 nm to 500 nm.

The height h1 (depth) of the rough portion 10dp is the same as the length between the bottom portion 10d and the top portion 10p along the Z axis direction. The height h1 is, for example, 1.5 times or more (for example, 2 times or more) as large as the peak wavelength. The height h1 is, for example, from 400 nm to 2 μm.

By providing the rough portion 10dp having such a size, a traveling direction of light emitted from the third layer 15 changes at the first surface 10a. As a result, light extraction efficiency is improved. In the semiconductor light-emitting device 110, the first surface 10a is a light exiting surface (emission face). The first surface 10a is, for example, a light extraction surface of the light emitting element.

When the rough portion 10dp is formed by, for example, wet etching, the bottom portion 10d is likely to be conical or pyramidal shaped. The rough portion 10dp may also be formed by, for example, dry etching. In this case, the bottom portion 10d may be formed in an arbitrary shape depending on dry etching conditions.

The insulating layer 30 is provided on the first surface 10a. For example, the third layer 15 is provided on the second layer 20, and the first layer 10 is provided on the third layer 15. The insulating layer 30 is provided on the first layer 10.

The insulating layer 30 is formed of, for example, any one of silicon oxide, silicon nitride, and silicon oxynitride. However, the material of the insulating layer 30 is not limited to these materials and other insulating materials may be adopted as the material of insulating layer 30.

The insulating layer 30 includes, for example, a first portion 30a and a second portion 30b. The first portion 30a is positioned on the bottom portion 10d. The first portion 30a overlaps the bottom portion 10d in the Z axis direction. The second portion 30b is positioned on the top portion 10p. The second portion 30b overlaps the top portion 10p in the Z axis direction.

The height of an upper end of the first portion 30a is lower than the height of the top portion 10p. That is, the first portion 30a includes a first end 30ad (bottom end) and a second end 30ap (top end). The first end 30ad is positioned on the bottom portion 10d side. The second end 30ap is positioned on a side opposite the first end 30ad. A distance between the second end 30ap and the second layer 20 along the Z axis direction (first direction moving from the second layer 20 to the first layer 10) is set as a first distance d1. A distance between the top portion 10p and the second layer 20 along the Z axis direction is set as a second distance d2. In the embodiment, the first distance d1 is shorter than the second distance d2.

The first portion 30a has a first thickness t1 along the Z axis direction. The second portion 30b has a second thickness t2 along the Z axis direction. In the embodiment, the first thickness t1 is larger than the second thickness t2.

That is, on the bottom portion 10d, the thickness of the insulating layer 30 is set to be locally thick. On the other hand, on the top portion 10p, the thickness of the insulating layer 30 is set to be relatively thin. That is, here the insulating layer 30 is not conformally deposited on the entire surface 10a, but rather valleys/depressions (bottom portions 10d) in the first layer 10 are filled with insulating layer whereas the peaks/heights (top portions 10p) have a relatively thin coating of insulating layer 30 thereon.

The first thickness t1 is, for example, from 200 nm to 1000 nm. On the other hand, the second thickness t2 is less than 200 nm.

For example, the first thickness t1 is from 200 nm to 500 nm. The second thickness t2 is 100 nm or less.

The first thickness t1 is, for example, 1.2 times to 10 times as large as the second thickness t2. The first thickness t1 may be, for example, 2 times to 5 times as large as the second thickness t2.

For example, a side surface 10s of the bottom portion 10d is tilted (angled) with respect to the Z axis direction. That is, the side surface 10s is tilted with respect to the X-Y plane. An angle between the side surface 10s and the X-Y plane is a tilt angle θ. The tilt angle θ is, for example, approximately 60°. When the first layer 10 is substantially a nitride semiconductor layer of a c surface crystal orientation, and when the rough portion 10dp is formed by wet etching, the tilt angle θ is approximately 62°. This value of the tilt angle θ is an example and the tilt angle θ may be arbitrarily set.

On a portion of the side surface 10s near the top portion 10p, the insulating layer 30 is relatively thin as compared to the thickness on the side surface 10s near the bottom portion 10d. As the thickness of the thin insulating layer 30, a thickness (layer thickness) thereof in a direction normal to the side surface 10s may be used. For example, the insulating layer 30 includes a portion provided on the side surface 10s. The portion provided on the side surface 10s has a third thickness t3 along the direction normal to the side surface 10s. A thickness of the portion provided on the side surface 10s along the Z axis direction is set as a fourth thickness t4. When the side surface 10s is planar, for example, a relationship of t4=t3/(cos θ) is satisfied. When the angle θ is approximately 60°, the fourth thickness t4 is approximately 2 times as large as the third thickness t3.

For example, the second thickness t2 of the second portion 30b provided on the top portion 10p may be substantially the same as the fourth thickness t4.

For example, in a reference example in which the insulating layer 30 is formed on the first surface 10a with a substantially uniform thickness (conformal coating), the first thickness t1 is substantially the same as the second thickness t2. In the first embodiment, the thickness of the insulating layer 30 is thicker on the bottom portion 10d than on the top portion 10p.

As a result, as described below, insulation resistance in the vicinity of the bottom portion 10d is increased. As a result, a semiconductor light-emitting device having high reliability may be provided.

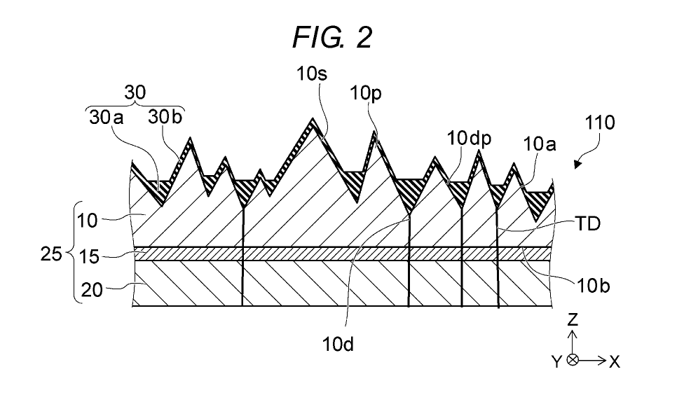

FIG. 2 is a schematic cross-sectional view illustrating the semiconductor light-emitting device according to the first embodiment.

As illustrated in FIG. 2, in the semiconductor light-emitting device 110, the first layer 10 may include a threading dislocation TD. The threading dislocation TD leads to, for example, the bottom portion 10d of the first layer 10. The threading dislocation TD may further extend to the third layer 15 and the second layer 20 from the first layer 10. As described below, the rough portion 10dp is formed by removing a portion of a layer which is to form the first layer 10 by etching or the like. At this time, in many cases, an etching rate of a portion where the threading dislocation TD is generated is higher than an etching rate of the other portions. Therefore, when the rough portion 10dp is formed by etching, the portion where the threading dislocation TD is present is likely to form the bottom portion 10d as a result. That is, for example, the threading dislocation TD is likely to be at or adjacent to the bottom portion 10d.

When an electrostatic discharge (ESD) testing is performed using a semiconductor light-emitting device, many portions where a defect occurred due to ESD are at or near the bottom portion 10d. For example, when observed with a microscope after an ESD test, abnormal portions were found at or near the bottom portion 10d.

For example, a charge is introduced into the first surface 10a by ESD. On the other hand, as described below, an electrode is electrically connected to the second layer 20. It is considered that the ESD charge introduced into the first surface 10a flows to the electrode through the first layer 10, the third layer 15, and the second layer 20. At this time, it is considered that this charge mainly passes through a portion where the distance between the first surface 10a and the second layer 20 is short. Due to this passage of the charge, a current locally flows, and the temperature therefore locally increases. It is considered that, due to this local temperature increase, a semiconductor layer changes (deteriorates) and is damaged by the localized heating.

In the laminate 25, a distance between the bottom portion 10d and the second layer 20 is shorter than a distance between the top portion 10p and the second layer 20. When the shape of the bottom portion 10d is conical, the distance between the first surface 10a and the second layer 20 locally decreases towards the bottom portion 10d. For example, when charge is present at the first surface 10a due to ESD, the charge is concentrated on the bottom portion 10d. It is considered that breakdown occurs at the bottom portion 10d and in the vicinity thereof where the distance between the first surface 10a and the second layer 20 is locally short.

In the first embodiment, the insulating layer 30 is provided on the first surface 10a. Charge is introduced into the surface of the insulating layer 30 by ESD. Due to the insulating layer 30, the charge is inhibited from passing through the first layer 10, the third layer 15, and the second layer 20. It is considered that the charge is discharged through, for example, a side surface of the laminate 25 (and a protective layer or the like provided in the side surface). At this time, deterioration in the laminate 25 is not likely to occur. As a result, a semiconductor light-emitting device having a high ESD resistance may be obtained.

In the first embodiment, the insulating layer 30 is particularly thick at the bottom portion 10d. As a result, increased insulation resistance may be obtained at the likely location(s) for breakdown by ESD.

However, when the entire portion of the insulating layer 30 is made thick, light absorption due to the insulating layer increases. Therefore, light extraction efficiency decreases. Further, when the entire portion of the insulating layer 30 is made thick (for example, thick enough to cover the peaks (10p) of the first layer), cracking is more likely to occur in the insulating layer 30. Furthermore, when the entire portion of the insulating layer 30 is excessively thick, heat retention increases because the thermal conductivity of the insulating layer 30 is generally lower than that of a semiconductor layer (for example, a nitride semiconductor) such as the first layer 10. Accordingly, when the entire portion of the insulating layer 30 is excessively thick, heat dissipation deteriorates.

On the other and, in the first embodiment, the first thickness t1 of the first portion 30a positioned on the bottom portion 10d is larger than the second thickness t2 of the second portion 30b positioned on the top portion 10p. As a result, sufficient insulation resistance may be obtained by providing the thick insulating layer 30 at the bottom portion 10d. Since the insulating layer 30 is thin on the top portion 10p which has little effect on insulation resistance, an increase in light absorption due to the insulating layer 30 may be suppressed. As a result, high light extraction efficiency may be obtained. Cracking of insulating layer 30 may also be suppressed in this manner. Further, high heat dissipation may still be obtained.

That is, according to the first embodiment, not only high light output efficiency but also high ESD resistance may be obtained. According to the first embodiment, a semiconductor light-emitting device having high reliability may also be provided.

When the thickness (third thickness t3) of the insulating layer 30 is excessively thin, a pin hole or the like may be formed, which may decrease reliability. Therefore, the thickness (third thickness t3) is preferably 15 nm or more. For example, when the angle θ is approximately 60°, the second thickness t2 (and the fourth thickness t4) is preferably 30 nm or more. For example, the second thickness t2 (and the fourth thickness t4) is preferably from 30 nm to 150 nm.

On the other hand, a third distance d3 between the bottom portion 10d and the second layer 20 in the Z axis direction is preferably from 20 nm to 200 nm. When the third distance d3 is excessively short, insulation resistance deteriorates. When the third distance d3 is excessively long, the thickness of the laminate 25 excessively increases. As a result, for example, heat dissipation deteriorates.

In the first embodiment, since the second portion 30b is provided in the insulating layer 30, the top portion 10p is also covered with the insulating layer 30. The second portion 30b of the insulating layer 30 functions as, for example, a passivation film. As a result, for example, the infiltration of impurities or the like into the first layer 10 is suppressed by the presence of insulating layer 30, and high reliability may be obtained.

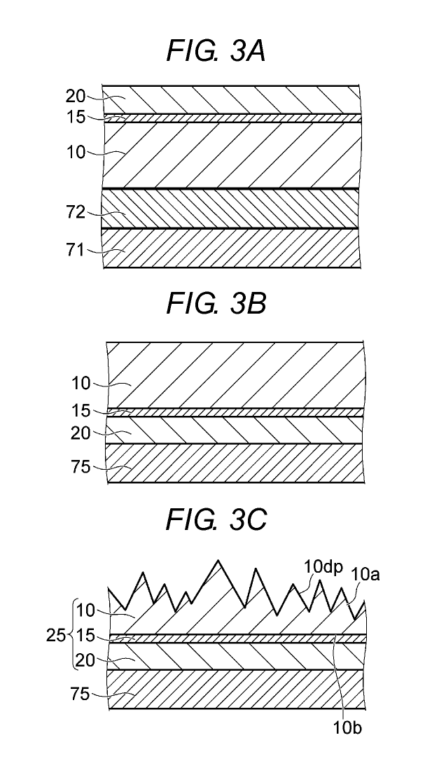

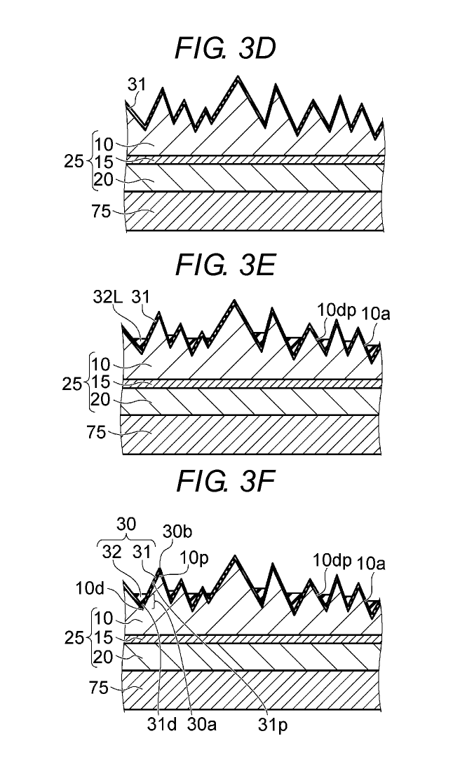

FIGS. 3A to 3F are schematic cross-sectional views illustrating steps of a method of manufacturing the semiconductor light-emitting device according to the first embodiment.

As illustrated in FIG. 3A, a buffer layer 72 is formed on a substrate 71. The substrate 71 is formed of, for example, anyone of Si, SiO₂, quartz, sapphire, GaN, SiC, and GaAs. When the substrate 71 has an arbitrary plane orientation and is formed of Si, for example, at least one of an AlN layer, an AlGaN layer, and a GaN layer, or a laminate structure thereof may be used as the buffer layer 72.

The first layer 10 is formed on the buffer layer 72. For example, an undoped GaN layer is formed as a portion of first layer 10, and then, n-type first semiconductor layer 11 is formed on the undoped GaN layer. As the first semiconductor layer 11, a GaN layer containing an n-type impurity is used. As the n-type impurity, at least one of Si, Ge, Te, and Sn is used. The first semiconductor layer 11 includes, for example, an n-side contact layer.

The third layer 15 is formed on the first layer 10. For example, the third layer 15 includes InₓGa₁₋ₓN (0<x<1), which is to form the well layers WL, and GaN layers, which are to form the barrier layers BL, alternately stacked on each other. The band-gap energy of the barrier layers BL is higher than the band-gap energy of the well layers WL.

The second layer 20 is formed on the third layer 15. As the second layer 20, for example, a GaN layer containing a p-type impurity is formed. As the p-type impurity, at least one of Mg, Zn, and C may be used. The second layer 20 includes, for example, a p-side contact layer.

As illustrated in FIG. 3B, after a support portion 75 is bonded to the second layer 20, the substrate 71 is removed. At this time, at least a part of the buffer layers 72 may be removed. A part of the buffer layers 72 may remain. When a part of the buffer layers 72 remain, the remaining buffer layers 72 may be considered conceptually as a part of the first layer 10.

As illustrated in FIG. 3C, the rough portion 10dp is formed on the surface of the first layer 10. In order to form the rough portion 10dp, for example, at least one of wet etching and dry etching is used.

The laminate 25 is thus formed. This laminate 25 includes the first layer 10, the second layer 20, and the third layer 15 described above.

As illustrated in FIG. 3D, for example, a first insulating film 31 is formed on the rough portion 10dp. The first insulating film 31 ultimately forms a part of the insulating layer 30. For example, a silicon nitride layer (SiNₓ layer) is formed as the first insulating film 31. The first insulating film 31 is formed by, for example, sputtering or vapor deposition. The thickness (third thickness t3) of the first insulating film 31 is, for example, from 20 nm to 250 nm. The first insulating film 31 may be formed of SiO₂ or the like. The first insulating film 31 may contain, for example, one of silicon oxide, silicon nitride, and silicon oxynitride.

As illustrated in FIG. 3E, a liquid layer 32L is formed on a part of the first insulating film 31. The second insulating film 32 (further described below) is formed from the liquid layer 32L. For example, the liquid layer 32L is formed on a portion of the first insulating film 31 that is provided on the bottom portion 10d. The liquid layer 32L is formed of, for example, a liquid glass material, such as spin-on-glass type material. The liquid glass material is provided on the bottom portion 10d side of the rough portion 10dp. The liquid glass material is not substantially provided on a portion of the first insulating film 31 that is provided on the top portion 10p. The liquid glass material (solution) is coated by, for example, spin coating on the first surface 10a where the rough portion 10dp is provided.

Next, the liquid layer 32L is solidified and/or cured. For example, the solidification of the liquid layer 32L is accelerated by being heated.

As a result, as illustrated in FIG. 3F, the second insulating film 32 is formed from the liquid layer 32L. The second insulating film 32 contains, for example, silicon oxide. As a result, the semiconductor light-emitting device 110 illustrated in FIG. 1 may be obtained.

The portion of the first insulating film 31 that is provided on the top portion 10p corresponds to the second portion 30b of the insulating layer 30. A laminated film of the portion of the first insulating film 31 that is provided on the bottom portion 10d and the second insulating film 32 corresponds to the first portion 30a of the insulating layer 30.

In this way, the insulating layer 30 may include the first insulating film 31 and the second insulating film 32. The first insulating film 31 includes a portion 31d in contact with the bottom portion 10d and a portion 31p in contact with the top portion 10p. This portion 31d in contact with the bottom portion 10d is positioned between the second insulating film 32 and the bottom portion 10d.

The second insulating film 32 may be formed of the same material as that of the first insulating film 31. In this case, a boundary between the first insulating film 31 and the second insulating film 32 may not be observed or may be difficult to observe.

The second insulating film 32 maybe formed of a material different from that of the first insulating film 31. In this case, a boundary between the first insulating film 31 and the second insulating film 32 may be observed by observing a cross-section with a microscope.

For example, the first insulating film 31 is formed of one of silicon nitride and silicon oxynitride. A refractive index of silicon nitride is approximately 2.0. A refractive index of a polymer resin is, for example, 1.5. The refractive index decreases in order of a GaN layer, silicon nitride, a resin, and air. Light extraction efficiency is easily improved.

On the other hand, the second insulating film 32 may preferably formed of silicon oxide. The second insulating film 32 is relatively easily formed, for example, by using a spin coating method, and as such the second insulating film 32 may be formed with high productivity.

For example, the second insulating film 32 may contain silicon, oxygen, and hydrogen. For example, when the second insulating film 32 is formed from the liquid layer 32L, hydrogen contained in the liquid layer 32L may be present in the second insulating film 32.

As the liquid glass material, for example, spin on glass (SOG) is used. As a liquid glass material, a solution comprising Si, O, and H as components is used. A solution having desired properties may be obtained by adjusting the composition of the solution and changing a solidification method. The liquid glass material is coated on the first surface 10a and then is heated with, for example, a hot plate. The heating temperature is, for example, from 80° C. to 200° C. The heating time is, for example, from 0.5 minutes to 3 minutes. Next, the glass material is irradiated with ultraviolet rays. Next, the glass material is baked with, for example, a hot plate. The baking temperature is, for example, 200° C. The baking time is, for example, from 15 minutes to 1 hour. The baking is performed in, for example, a nitrogen atmosphere. It is preferable that the liquid glass material have a low thermal expansion coefficient. For example, a difference in expansion of the material between 200° C. and 400° C. may preferably be 2% or less. In order to obtain an excellent coating property, it is preferable that the liquid glass material (solution) have an appropriate viscosity.

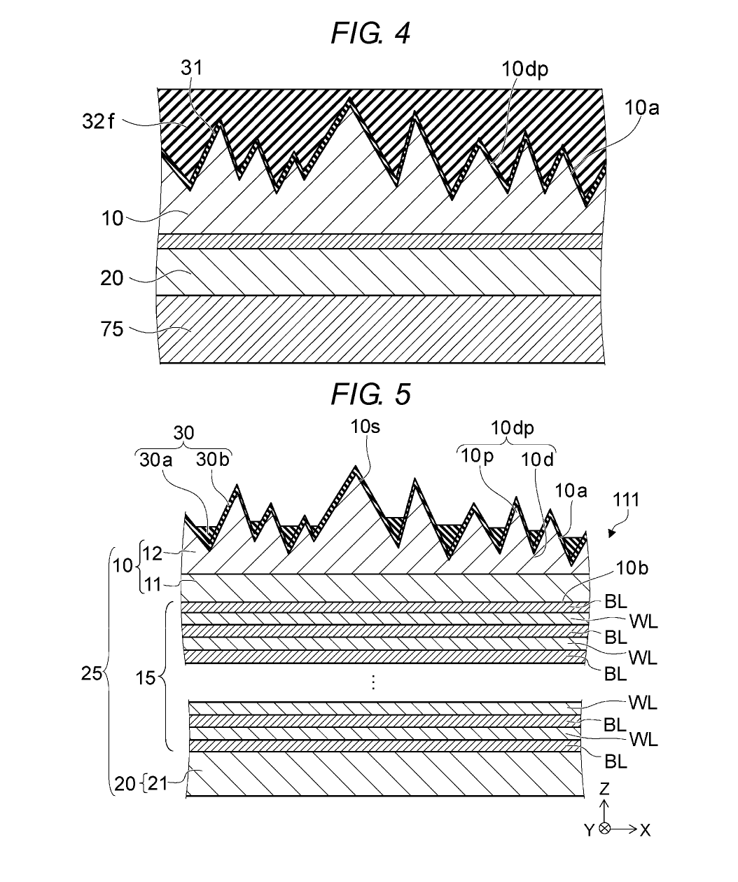

FIG. 4 is a schematic cross-sectional view illustrating another method of manufacturing the semiconductor light-emitting device according to the first embodiment.

FIG. 4 illustrates a step after the step illustrated in FIG. 3D. As illustrated above with reference to FIGS. 3A to 3D, the first insulating film 31 is formed on the first surface 10a of the laminate 25.

As illustrated in FIG. 4, a third insulating film 32f is formed on the first insulating film 31. The third insulating film 32f forms the second insulating film 32. The third insulating film 32f is formed to cover the first insulating film 31. For example, the third insulating film 32f is formed on the portion of the first insulating film 31 that is formed on the top portion 10p, and is formed to bury the bottom portion 10d.

Next, apart of the third insulating film 32f is removed. That is, a part of the third insulating film 32f is removed by etching. For example, the portion of the first insulating film 31 that is provided on the top portion 10p is exposed. A portion of the third insulating film 32f that is provided on the bottom portion 10d remains. The remaining portion of the third insulating film 32f forms the second insulating film 32.

In this method, it is preferable that a material of the third insulating film 32f be different from a material of the first insulating film 31. For example, an etching rate of the third insulating film 32f is different from an etching rate of the first insulating film 31. For example, an etching rate of the third insulating film 32f is higher than an etching rate of the first insulating film 31. As a result, a part of the third insulating film 32f may be removed while allowing a substantial portion or substantially all of the first insulating film 31 to remain after the etching process for removing a part of the third insulating film 32f, and thus the second insulating film 32 may be easily formed. The second insulating film 32 may be formed with high controllability.

For example, when the first insulating film 31 is formed of one of silicon nitride and silicon oxynitride, it is preferable that the third insulating film 32f (that is, the second insulating film 32) be formed of silicon oxide. As a result, different etching rates may be obtained.

In order to remove a part of the third insulating film 32f, for example, a hydrofluoric acid-based solution may be used. Alternatively, dry etching may be performed using fluorine-based gas.

FIG. 5 is a schematic cross-sectional view illustrating another semiconductor light-emitting device according to the first embodiment.

As illustrated in FIG. 5, in semiconductor light-emitting device 111, the first layer 10 further includes a low impurity concentration layer 12. The first semiconductor layer 11 is disposed between the low impurity concentration layer 12 and the third layer 15.

The concentration of a first conductivity type impurity in the first semiconductor layer 11 is higher than a concentration of an impurity in the low impurity concentration layer 12. For example, the first semiconductor layer 11 is formed of n-type GaN. The low impurity concentration layer 12 is formed of, for example, i-GaN (GaN not intentionally doped with an impurity). The low impurity concentration layer 12 may include at least a part of the buffer layer(s).

In this example, the bottom portion 10d is positioned in the low impurity concentration layer 12. The low impurity concentration layer 12 has lower electrical conductivity than the first semiconductor layer 11. By positioning the bottom portion 10d in the low impurity concentration layer 12, for example, the concentration of a current on the bottom portion 10d may be suppressed, and reliability may be improved.

In the semiconductor light-emitting device 111, a part of the low impurity concentration layer 12 is removed. In the removed part (not specifically depicted in FIG. 5), the first semiconductor layer 11 and an electrode are electrically connected.

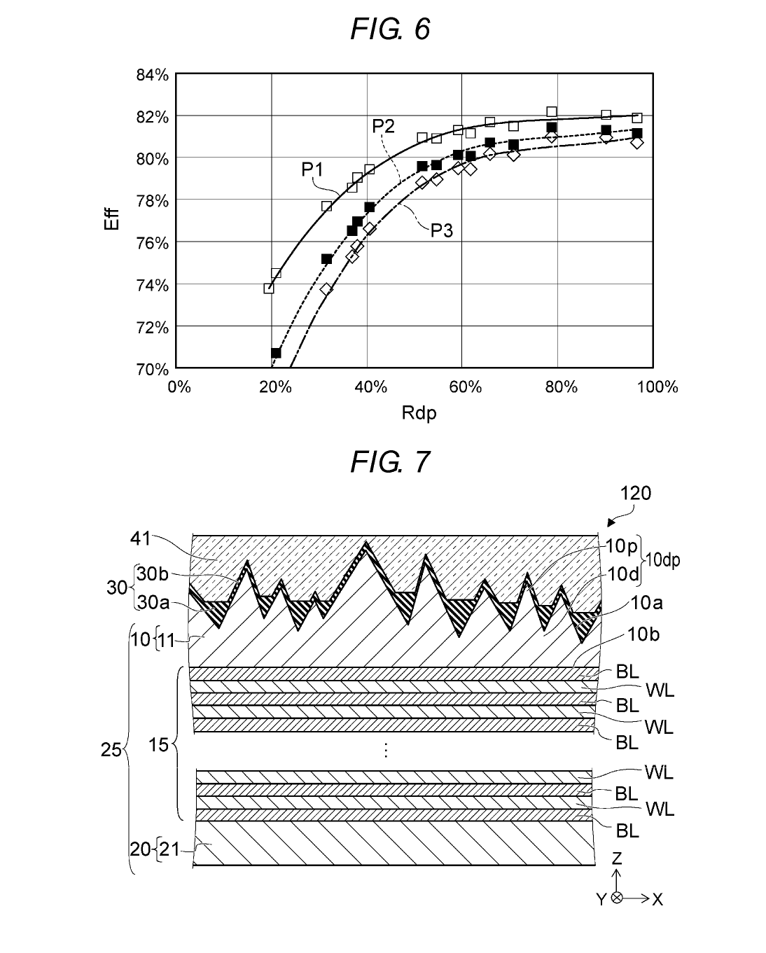

FIG. 6 is a graph illustrating characteristics of a semiconductor light-emitting device.

FIG. 6 illustrates the simulation results of light extraction efficiency. In this simulation, the plural hexagonal pyramid-shaped top portions 10p are provided in the flat first surface 10a, and the light extraction efficiency, which varies depending on the density of the top portions 10p, is calculated. The height of the hexagonal pyramid is 1 μm. A curve P2 represents a center value of the simulation results, and characteristic curves P1 and P3 correspond to the error upper limit and the error lower limit of the simulation, respectively.

In FIG. 6, the horizontal axis represents a ratio Rdp of the total area of the bottom surfaces of the plural hexagonal pyramids to the area of the first surface 10a. When the ratio Rdp is 0%, the entire portion of the first surface 10a is flat (parallel to the X-Y plane). When the ratio Rdp is 100%, the first surface 10a does not have a flat portion (surface parallel to the X-Y plane). In FIG. 6, the vertical axis represents the light extraction efficiency Eff (relative value).

As may be seen in FIG. 6, the higher the ratio Rdp is, the higher the light extraction efficiency Eff is. When the ratio Rdp is from 70% to 90%, an increase in the light extraction efficiency Eff is substantially saturated. In practice, the ratio Rdp is preferably 50% or higher, and more preferably 70% or higher. In other words, a ratio of the area of the plane parallel to the X-Y plane to the total area is preferably 50% or lower and more preferably 30% or lower.

The top surface (second end 30ap) of the first portion 30a of the insulating layer 30 may be substantially parallel to the X-Y plane. A ratio of the area of the top surface of the first portion 30a to the area of the first surface 10a is preferably 50% or lower and more preferably 30% or lower.

For example, when the height of the second end 30ap of the insulating layer 30 is low, the flat portion is relatively small. The height of the second end 30ap of the insulating layer 30 is preferably 0.2 times to 0.8 times as large as the height h1 of the rough portion 10dp. High ESD resistance and high light extraction efficiency may be obtained at these values.

The first thickness t1 is preferably 0.2 times to 0.8 times as large as the height h1 of the rough portion 10dp (the distance between the bottom portion 10d and the top portion 10p along the Z axis direction). As a result, high ESD resistance and high light extraction efficiency may be obtained.

When the laminate 25 is formed on a silicon substrate, the warpage of the substrate caused by a difference in thermal expansion coefficient between the silicon substrate and the laminate 25 increases. Therefore, it is difficult to increase the thickness of the first layer 10. For example, the thickness of the low impurity concentration layer 12 (for example, an undoped GaN layer) is from 2 μm to 3 μm. The thickness of the first semiconductor layer 11 (for example, a n-type GaN layer) is from 2 μm to 3 μm. When the rough portion 10dp is provided on the thin first layer 10, the formation of the rough portion 10dp varies, and thus a thin portion is likely to be locally formed on the first layer 10. For example, the thickness of a portion having low crystal quality (for example, a portion having a high threading dislocation density) is locally thin. Particularly, in such a portion, ESD breakdown is likely to occur.

Therefore, it is particularly advantageous to use the laminate 25 in which the insulating layer 30 is formed on a silicon substrate or the like. That is, it is particularly advantageous to combine the insulating layer 30 with the thin first layer 10 (thickness: 4 μm or less). For example, the distance (third distance d3) between the bottom portion 10d and the second layer 20 in the Z axis direction is preferably from 20 nm to 200 nm.

For example, the first semiconductor layer 11 is, for example, an n-type GaN cladding layer. A donor concentration in the first semiconductor layer 11 is, for example, 1×10¹⁹ cm⁻³. The thickness of the first semiconductor layer 11 is approximately 6 μm.

A superlattice layer may be provided between the first semiconductor layer 11 (part of first layer 10) and the third layer 15. In the superlattice layer, for example, plural InGaN layers and plural undoped InGaN layers are alternately laminated. The thickness of each of the plural InGaN layers is approximately 1 nm. The thickness of each of the plural undoped InGaN layers is approximately 3 nm. The number of plural InGaN layers is, for example, approximately 30.

The well layer WL is formed of InGaN. The thickness of the well layer WL is approximately 5 nm. The barrier layer BL is formed of undoped GaN. The thickness of the barrier layer BL is approximately 5 nm. The number of the well layers WL is, for example, 4.

The second semiconductor layer 21 includes, for example, a p-type AlGaN overflow suppressing layer (acceptor concentration: 1×10²⁰ cm⁻³, thickness: 5 nm), a p-type GaN cladding layer (acceptor concentration: 1×10²⁰ cm⁻³, thickness: 100 nm), and a p⁺-GaN contact layer (acceptor concentration: 1×10²¹ cm⁻³, thickness: 5 nm). For example, a p-side electrode is provided on the p⁺-GaN contact layer. On the other hand, plural electrodes may be provided in the first layer 10.

### Second Embodiment

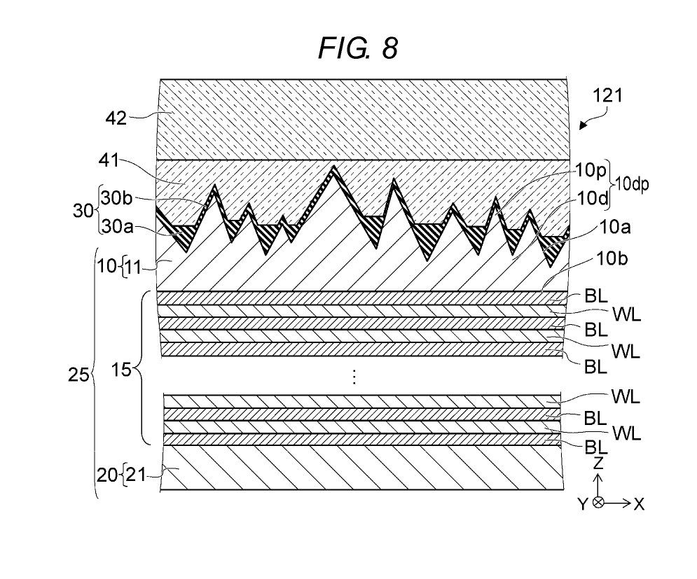

FIG. 7 is a schematic cross-sectional view illustrating a semiconductor light-emitting device according to a second embodiment.

As illustrated in FIG. 7, a semiconductor light-emitting device 120 further includes a light-transmitting layer 41. Since configurations other than the above configuration may be the same as the above-described semiconductor light-emitting devices 110 and 111, the description thereof will not be repeated.

The insulating layer 30 is disposed between the light-transmitting layer 41 and the first surface 10a. That is, the insulating layer 30 is provided on the first layer 10, and the light-transmitting layer 41 is provided on the insulating layer 30.

A part of the light-transmitting layer 41 is embedded in a space that is formed by the bottom portion 10d. That is, at least a part of the light-transmitting layer 41 is parallel to the top portion 10p in, for example, the X axis direction (second direction perpendicular to the Z axis direction).

The hardness of the light-transmitting layer 41 may be lower than the hardness of the insulating layer 30. For example, as described above, the insulating layer 30 is formed of, for example, any one of silicon oxide, silicon nitride, and silicon oxynitride. On the other hand, the light-transmitting layer 41 is formed of, for example, a resin. The light-transmitting layer 41 is formed of, for example, a silicone resin.

For example, in a reference example, the thickness of the insulating layer 30 is fixed and constant. In this case, the first thickness t1 is the same as the second thickness t2. When the insulating layer 30 is thickened in order to obtain high ESD resistance, it is difficult to deform the insulating layer 30. On the other hand, strain is generated in the laminate 25 due to stress by heat. Due to the strain generated in the laminate 25, a large stress is applied to an interface between the laminate 25 and the insulating layer 30. Therefore, deterioration or breakdown is likely to occur at the interface. On the other hand, when the thickness of the insulating layer 30 is thin as a whole to reduce stress at the interface, ESD resistance is insufficient.

In the second embodiment, high ESD resistance is secured by allowing a portion of the insulating layer 30 that is provided on the bottom portion 10d to be locally thick. In addition, by allowing a portion of the insulating layer 30 that is provided on the top portion 10p to be locally thin, the portion of the insulating layer 30 is easily deformed. That is, stress generated at an interface between the top portion 10p and the insulating layer 30 may be relaxed. Since the hardness of a portion between the top portions 10p is relatively low, the light-transmitting layer 41 which is easily deformed is provided. As a result, stress to be generated is relaxed, and reliability may be further improved.

In the second embodiment, a refractive index of the light-transmitting layer 41 may be lower than a refractive index of the first layer 10. For example, the first layer 10 is formed of a nitride semiconductor (for example, GaN). The light-transmitting layer 41 is formed of, for example, a silicone resin. The refractive index of GaN is approximately 2.4. The refractive index of the silicone layer is approximately from 1.50 to 1.55. Light emitted from the third layer 15 passes through the first layer 10 and the light-transmitting layer 41 in this order, and then is emitted to the outside of the system. Light extraction efficiency may be improved by light passing through regions having a high refractive index to a region having a low refractive index.

It is preferable that the refractive index of the insulating layer 30 be lower than the refractive index of the first layer 10 and be higher than the refractive index of the light-transmitting layer 41. As a result, light passes through regions in order from a region having a high refractive index to a region having a low refractive index. As a result, light extraction efficiency is improved.

The insulating layer 30 is relatively thin. In particular, the thickness (second thickness t2) of a portion of the insulating layer 30 that is provided on the top portion 10p is thin. Therefore, when the refractive index of the insulating layer 30 is higher than the refractive index of the light-transmitting layer 41, light is not likely to be reflected from an interface between the insulating layer 30 and the light-transmitting layer 41. For example, when the refractive index of the first layer 10 is approximately 2.4, and when the refractive index of the light-transmitting layer is approximately from 1.50 to 1.55, the refractive index of the insulating layer 30 may be approximately from 1.4 to 1.5.

FIG. 8 is a schematic cross-sectional view illustrating another semiconductor light-emitting device according to the second embodiment.

As illustrated in FIG. 8, another semiconductor light-emitting device 121 according to the second embodiment is the same as the semiconductor light-emitting device 120, except that a wavelength conversion layer 42 is further provided.

The light-transmitting layer 41 is disposed between the wavelength conversion layer 42 and the insulating layer 30. The wavelength conversion layer 42 absorbs at least a part of first light emitted from the third layer 15, and emits second light. A wavelength of the second light is different from a wavelength of the first light. For example, the first light contains at least one of ultraviolet rays, purple light, and blue light. The second light contains at least one of yellow light and red light. Combined light of the first light and the second light is, for example, substantially white, though the color of the combined light is arbitrary. The wavelength conversion layer 42 is, for example, a phosphor layer. By using the wavelength conversion layer 42, light having an arbitrary color may be obtained.

### Third Embodiment

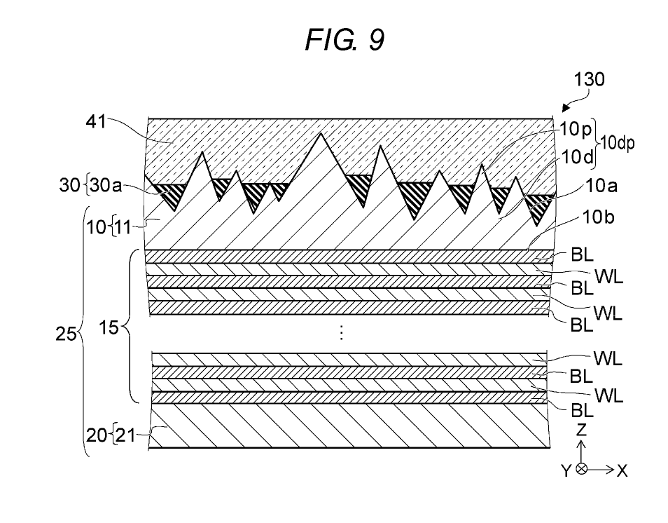

FIG. 9 is a schematic cross-sectional view illustrating a semiconductor light-emitting device according to a third embodiment.

As illustrated in FIG. 9, in a semiconductor light-emitting device 130 according to the third embodiment, the light-transmitting layer 41 is provided. In the insulating layer 30, the first portion 30a is provided; however, the second portion 30b is not provided. Since configurations other than the above configuration may be set to be the same as the above-described semiconductor light-emitting devices 110 and 111, the description thereof will not be repeated.

In the semiconductor light-emitting device 130, the first portion 30a is provided on the bottom portion 10d. Therefore, high ESD resistance may be obtained. For example, stress is relaxed by the light-transmitting layer 41.

FIG. 10 is a schematic cross-sectional view illustrating another semiconductor light-emitting device according to the third embodiment.

As illustrated in FIG. 10, another semiconductor light-emitting device 131 is the same as the semiconductor light-emitting device 130, except that a wavelength conversion layer 42 is further provided. By using the wavelength conversion layer 42, light having an arbitrary color may be obtained.

### Fourth Embodiment

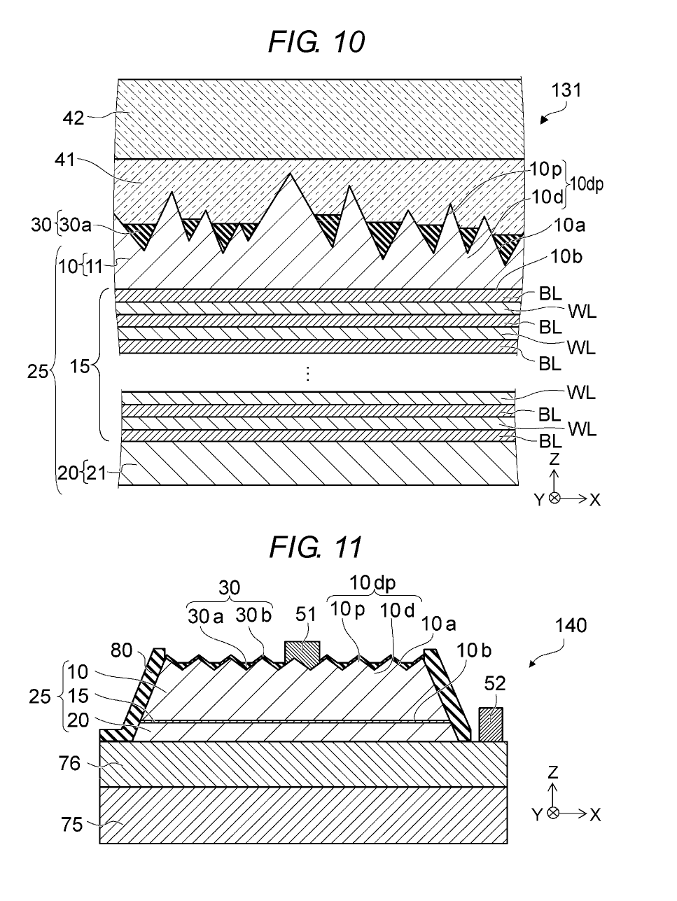

FIG. 11 is a schematic cross-sectional view illustrating a semiconductor light-emitting device according to a fourth embodiment.

As illustrated in FIG. 11, in a semiconductor light-emitting device 140 according to the embodiment, a first electrode 51, a second electrode 52, a support portion 75, a conductive layer 76, and a passivation film 80 are provided.

The conductive layer 76 is provided on the support portion 75. The second layer 20 is provided on the conductive layer 76. The third layer 15 is provided on the second layer 20. The first layer 10 is provided on the third layer 15. The top surface of the first layer 10 corresponds to the first surface 10a. The rough portion 10dp is provided on the first surface 10a. The insulating layer 30 including the first portion 30a and the second portion 30b is provided on the first surface 10a. A part of the insulating layer 30 is removed, and the first electrode 51 is electrically connected to the first layer 10. A conductive film (not specifically depicted) may be provided between the first layer 10 and the first electrode 51.

The conductive layer 76 is connected to the second layer 20 and the electrodes. A conductive film (not illustrated) maybe provided between the second layer 20 and the conductive layer 76. The second electrode 52 is provided on a part of the conductive layer 76.

By applying a voltage between the first electrode 51 and the second electrode 52, a current is supplied to the third layer 15 through the first layer 10 and the second layer 20, and thus light is emitted from the third layer 15.

In the semiconductor light-emitting device 140, the rough portion 10dp including the bottom portion 10d and the top portion 10p is provided on the top surface (first surface 10a) of the first layer 10. The thick first portion 30a and the thin second portion 30b are provided on the insulating layer 30. As a result, high ESD resistance may be obtained. In the semiconductor light-emitting device 140, the light-transmitting layer 41 and the wavelength conversion layer 42 may be further provided.

### Fifth Embodiment

This embodiment relates to a method of manufacturing a semiconductor light-emitting device.

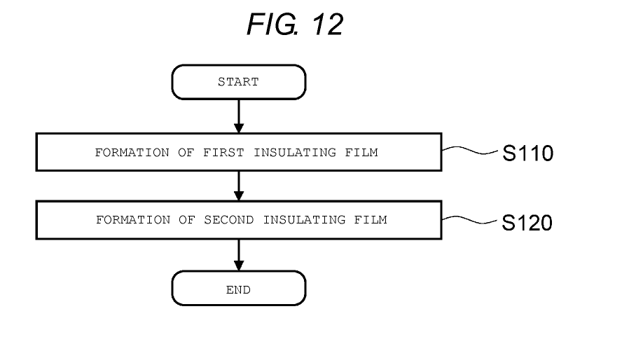

FIG. 12 is a flowchart illustrating a method of manufacturing a semiconductor light-emitting device according to a fifth embodiment.

As illustrated in FIG. 12, in the method of manufacturing a semiconductor light-emitting device according to the embodiment, the first insulating film 31 is formed (Step S110). In this step, first insulating film 31 is formed on the laminate 25, the laminate 25 includes: the first layer 10 that includes the first semiconductor layer 11 of the first conductivity type; the second layer 20 that includes the second semiconductor layer 21 of the second conductivity type; and the third layer 15 that is provided between the first layer 10 and the second layer 20. The first layer 10 has the first surface 10a and the second surface 10b, in which the first surface 10a has the rough portion 10dp including the bottom portion 10d and the top portion 10p, and the second surface 10b is opposite the first surface 10a. The third layer 15 is provided between the second surface 10b and the second layer 20. The first insulating film 31 is provided to cover the bottom portion 10d and the top portion 10p of the laminate 25. For example, the process described above with reference to FIG. 3D is performed.

The second insulating film 32 is formed on the portion of the first insulating film 31 that is provided on the bottom portion 10d (Step S120).

During the formation of the second insulating film 32, for example, the liquid layer 32L which is to form second insulating film 32 is formed on the portion of the first insulating film 31 that is provided on the bottom portion 10d. The liquid layer 32L is solidified to form the second insulating film 32. That is, for example, the processes described above with reference to FIGS. 3E and 3F are performed.

Alternatively, the second insulating film 32 may be formed by forming the third insulating film 32f (which is subsequently formed into the second insulating film 32) to cover the first insulating film 31 and then removing a part of the third insulating film 32f. That is, the process described above with reference to FIG. 4 is performed.

The portion of the first insulating film 31 that is provided on the top portion 10p corresponds to the second portion 30b of the insulating layer 30. A laminated film of the portion of the first insulating film 31 that is provided on the bottom portion 10d and the second insulating film 32 corresponds to the first portion 30a of the insulating layer 30. According to the method, a semiconductor light-emitting device with high reliability may be manufactured with high productivity.

In the semiconductor light-emitting device and the method of manufacturing a semiconductor light-emitting device according to the embodiments, examples of a growth method of a semiconductor layer (crystal layer) include a metal-organic chemical vapor deposition (MOCVD) method, a metal-organic vapor phase epitaxy (MOVPE) method, a molecular beam epitaxy (MBE) method, and a halide vapor phase epitaxy (HYPE) method.

For example, when the MOCVD method or the MOVPE method is used, the materials for forming the respective semiconductor layers (crystal layers) are as follows. As a material of Ga, for example, trimethyl gallium (TMGa) and triethyl gallium (TEGa) maybe used. Asa material of In, for example, trimethyl indium (TMIn) and triethyl indium (TEIn) may be used. As a material of Al, for example, trimethyl aluminum (TMAl) may be used. As a material of N, for example, ammonia (NH₃), monomethyl hydrazine (MMHy), and dimethyl hydrazine (DMHy) may be used. As a material of Si, monosilane (SiH₄) and disilane (Si₂H₆) may be used.

According to the disclosure, a semiconductor light-emitting device having high reliability and a method of manufacturing the same are described.

In this disclosure, “nitride semiconductor” includes all the semiconductor materials having a composition in which, in the chemical formula BₓIn_{y}Al_{z}Ga_{1-x-y-z}N (wherein 0≦x≦1, 0≦y≦1, 0≦z≦1, x+y+z≦1), the composition ratios x, y, and z satisfy the respective ranges. In addition, “nitride semiconductor” also includes a semiconductor having a composition in which a group V element other than nitrogen (N) is further added in the above-described chemical formula; a semiconductor having a composition in which various elements (e.g., dopants) are further added to control various physical properties such as a conductivity type in the above-described chemical formula; and a semiconductor material having a composition otherwise corresponding to the above chemical formula but further including various elements which are unintentionally present as impurities at levels which are technologically and/or economically infeasible to reduce or eliminate in the above-described chemical formula is also considered “nitride semiconductor.”

In this disclosure, “perpendicular” and “parallel” refer to not only “exactly perpendicular” and “exactly parallel” but also to “substantially perpendicular” and “”substantially parallel” in which, for example, a variation from exactness due to the manufacturing steps is tolerable.

Hereinabove, the embodiments are described with reference to the specific examples. However, the embodiments are not limited to these specific examples. For example, any specific configurations of the respective components such as the first to third layers, the semiconductor layers, the insulating layer, the electrodes, and the support portion included in the semiconductor light-emitting device are encompassed within the scope of the embodiments as long as those skilled in the art may similarly practice the embodiments and achieve similar effects by appropriately selecting such configurations from well-known ones.

In addition, any combinations of two or more components of the respective specific examples are encompassed within the scope of the embodiments within a range not departing from the concepts of the embodiments.

Further, all the semiconductor light-emitting devices and the methods of manufacturing the same, which are appropriately modified by those skilled in the art based on the semiconductor light-emitting device and the method of manufacturing the same according to the embodiments, are also encompassed within the embodiments within a range not departing from the concepts of the embodiments.

Furthermore, various changes and modifications which may be conceived by those skilled in the art in the scope of the embodiments are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting device, comprising:
a first layer having a first surface and a second surface opposing the first surface and spaced from the first surface in a first direction crossing the second surface, the first layer including a first semiconductor layer of a first conductivity type, the first surface of the first layer having a roughness including a bottom portion and a top portion, a first distance along the first direction between the bottom portion and the second surface being less than a second distance along the first direction between the top portion and the second surface;
a light emitting layer adjacent to the second surface;
a second layer including a second semiconductor layer of a second conductivity type, the light emitting layer being between the second surface and the second layer in the first direction; and
an insulating layer on the first surface, wherein
the insulating layer includes a first portion adjacent to the bottom portion and a second portion adjacent to the top portion, and
a first thickness of the first portion along the first direction is greater than a second thickness of the second portion along the first direction.

2. The semiconductor light-emitting device according to claim 1, wherein the first thickness is 0.2 times to 0.8 times a distance between the bottom portion and the top portion along the first direction.

3. The semiconductor light-emitting device according to claim 1, wherein the first thickness is from 200 nm to 1,000 nm.

4. The semiconductor light-emitting device according to claim 3, wherein the second thickness is less than 200 nm.

5. The semiconductor light-emitting device according to claim 1, wherein the second thickness is less than 200 nm.

6. The semiconductor light-emitting device according to claim 1, wherein the insulating film includes:
a first insulating film contacting the bottom portion and the top portion; and
a second insulating film on the first insulating film, the first insulating film being between the bottom portion and the second insulating film in the first direction.

7. The semiconductor light-emitting device according to claim 6, wherein
the first insulating film is one of a silicon nitride and a silicon oxynitride, and
the second insulating film is a silicon oxide.

8. The semiconductor light-emitting device according to claim 1, further comprising:
a light-transmitting layer on the insulating layer, the insulating layer being between the light-transmitting layer and the first surface, and
at least a portion of the light-transmitting layer is at a distance along the first direction from the second surface that is equal to or greater than the second distance.

9. The semiconductor light-emitting device according to claim 8, wherein a refractive index of the light-transmitting layer is lower than a refractive index of the first layer.

10. The semiconductor light-emitting device according to claim 1, wherein a distance along the first direction between the bottom portion and the second layer is between 20 nm and 200 nm.

11. A light-emitting device, comprising:
a light emitting body including a light emitting layer and a first surface from which light generated in the light emitting layer is to be emitted, the first surface having a roughness including a peak portion and a valley portion; and
a first insulating material filling the valley portion to a first thickness along a first direction crossing the light emitting layer, the first thickness being less than a distance along the first direction from a point in the valley portion that is closest to the light emitting layer to a point in the peak portion that is farthest from the light emitting layer.

12. The light-emitting device according to claim 11, further comprising:
a first insulating layer coating the first surface with a conformal thickness that is less than the first thickness, the first insulating layer being between the first insulating material and the first surface.

13. The light-emitting device according to claim 12, wherein the first insulating material is a silicon oxide and the first insulating layer is one of a silicon nitride and a silicon oxynitride.

14. The light-emitting device according to claim 11, further comprising:
a transparent resin layer on first insulating material, the transparent resin layer extending along the first direction from the first insulating material to a distance from the light emitting layer that is beyond the point in the peak portion farthest from the light emitting layer.

15. A method of manufacturing a semiconductor light-emitting device, the method comprising:
forming a laminate body including:
a first layer having a first surface and a second surface opposing the surface and spaced from the first surface in a first direction crossing the second surface, the first layer comprising a first semiconductor layer of a first conductivity type, the first surface of the first layer having a roughness including a bottom portion and a top portion, a first distance along the first direction between the bottom portion and the second surface being less than a second distance along the first direction between the top portion and the second surface,
a light emitting layer adjacent to the second surface, and
a second layer including a second semiconductor layer of a second conductivity type, the light emitting layer being between the second surface and the second layer in the first direction; and
forming an insulating layer on the first surface, the insulating layer including a first portion adjacent to the bottom portion and a second portion adjacent to the top portion, wherein
a first thickness of the first portion along the first direction is greater than a second thickness of the second portion along the first direction.

16. The method according to claim 15, wherein the wherein the insulating layer comprises:
a first insulating film contacting the bottom portion and the top portion; and
a second insulating film on the first insulating film, the first insulating film being between the bottom portion and the second insulating film in the first direction.

17. The method according to claim 16, wherein the first insulating film is a conformally coated film comprising at least one of silicon nitride and silicon oxynitride, and the second insulating film is a spin-on-glass material.

18. The method according to claim 15, wherein forming the insulating layer comprises:
forming a first insulating film by a vapor deposition process, the first insulating film being disposed on the top and bottom portions; and
forming a second insulating film on the first insulating film by applying a liquid-state precursor material, then solidifying the liquid-state precursor material.

19. The method according to claim 18, wherein the second insulating film is not formed on the first insulating film adjacent in the first direction to the top portion.

20. The method according to claim 18, wherein the second insulating film completely covers the first insulating film after solidification of the liquid-state precursor material, and an etchant is used to remove portions of the second insulating film so as to expose the first insulating film adjacent to the top portion.
